(19) United States
(12) Patent Application Publication
(10) Pub. No.: US 2026/0312548 A1
(43) Pub. Date: Oct. 8, 2026

(54) POWER AMPLIFIER SYSTEMS WITH LOAD CONTROL

(71) Applicant: Skyworks Solutions, Inc., Irvine, CA (US)

(72) Inventors: Nathan Lucas Nuzum, Quasqueton, IA (US); Curtis Lee Mayberry, Cedar Rapids, IA (US)

(21) Appl. No.: 19/710,972

(22) Filed: Jun. 17, 2026

Related U.S. Application Data
(63) Continuation of application No. 18/131,527, filed on Apr. 6, 2023, now Pat. No. 12,695,432.
(60) Provisional application No. 63/329,247, filed on Apr. 8, 2022.
(60) Provisional application No. 63/329,236, filed on Apr. 8, 2022.

(51) Int. Cl. H03F 3/213; H03F 1/02; H03F 1/56; H03F 3/24

(52) U.S. Cl. CPC H03F 3/213; H03F 1/0233; H03F 1/565; H03F 3/245; H03F 2200/06; H03F 2200/09; H03F 2200/451

(57) ABSTRACT

A power amplification system is provided comprising: a power amplifier circuit, the power amplifier circuit including a plurality of transistors; and a frequency response compensation circuit for providing a plurality of values of capacitance. The frequency response compensation circuit having at least one tuning capacitor. Each of the at least one tuning capacitors is coupled to a tuning switch for regulating the current path to and/or from the corresponding capacitor to control the value of the capacitance provided by the frequency response compensation circuit. The frequency response compensation circuit is coupled to at least two of the transistors of the power amplifier circuit. The frequency response compensation circuit is configured to reduce variation over frequency of a load impedance of the power amplification system. A wireless device comprising such a power amplification system is also provided. A wireless module comprising such a power amplification system is also provided.

### INCORPORATION BY REFERENCE TO ANY PRIORITY APPLICATIONS

This application is a continuation of U.S. patent application Ser. No. 18/131,527, filed Apr. 6, 2023, which claims the benefit of U.S. Provisional Patent Application No. 63/329,247, filed Apr. 8, 2022, and U.S. Provisional Patent Application No. 63/329,236, filed Apr. 8, 2022, the entireties of which are hereby incorporated by reference herein and made a part of the present disclosure. Any and all applications for which a foreign or domestic priority claim is identified in connection with the present application are hereby incorporated by reference under 37 C.F.R. § 1.57 in their entirety herein and made a part of the present disclosure.

### FIELD OF THE INVENTION

The present disclosure generally relates to power amplifiers, and particularly to power amplifier systems for RF applications.

### BACKGROUND OF THE INVENTION

Radio-frequency (RF) communications devices and systems may comprise or be connected to an antenna to transmit and receive signals. Such devices and systems may also comprise additional components and circuitry for processing signals transmitted and received via the antenna. For example, RF communications devices and systems using a cellular standard, a wireless local area network (WLAN) standard, and/or any other suitable communication standard may comprise or be connected to one or more power amplifiers for amplifying a signal transmitted or received via the antenna.

Such a power amplifier may be a push-pull amplifier used for envelope tracking. While a push-pull amplifier can be implemented for a number of RF communication devices and systems, a need exists for a better amplification system design to improve various parameters, such as rejection of second harmonics, lower power supply rail capacitance, and power efficiency.

### BRIEF SUMMARY OF THE INVENTION

The invention is defined by the claims. Optional features are detailed in the dependent claims.

According to a number of embodiments of a first aspect, a power amplification system is provided, the power amplification system comprising: a power amplifier circuit; an output power control circuit for providing a plurality of values of capacitance, and a balun coupled to the power amplifier circuit and to the output power control circuit. The output power control circuit comprises at least one load control capacitor. Each of the at least one load control capacitor is coupled to a load control switch for regulating the current path to and/or from the corresponding capacitor to control the value of the capacitance provided by the output power control circuit.

Optionally, the power amplifier circuit may comprise a plurality of transistors.

Optionally, at least two of the transistors of the power amplifier circuit may be differential transistors.

Optionally, the power amplifier circuit may comprise a push-pull amplifier.

Optionally, the balun may comprise a first coil having a first end and a second end, the first end of the first coil being coupled to a first differential transistor and the second end of the first coil being coupled to a second differential transistor.

Optionally, the first end of the first coil may be coupled to a drain or a collector of the first differential transistor and the second end of the first coil may be coupled to a drain or a collector of the second differential transistor.

Optionally, the balun may comprise a second coil having a first end and a second end, the first end of the second coil being coupled to an RF output node and the second end of the second coil being coupled to a ground.

Optionally, the second end of the second coil may be coupled to the ground via one or more termination capacitors.

Optionally, at least one of the termination capacitors may be a surface-mount capacitor.

Optionally, the output power control circuit may be coupled with at least one of the termination capacitors.

Optionally, at least one of the load control capacitors and at least one of the termination capacitors may be connected in parallel.

Optionally, a capacitance of the balun may be dependent on one or more of: the value of the termination capacitor of the balun, the value of the capacitance provided by the output power control circuit, whether the termination capacitor and the output power control circuit are connected in parallel or in series, and whether the load control switch is on or off.

Optionally, the output power control circuit may provide low capacitance having a value close to zero when the load control switch is off.

Optionally, when the load control switch is off, the output power control circuit may not provide additional capacitance to the balun, and the power amplification system may have a load impedance value that leads to a lower output power.

Optionally, when the load control switch is on, the output power control circuit may provide additional capacitance to the balun, causing a load impedance value to decrease and output power of the power amplification system to increase to a higher output power.

Optionally, an output power of the power amplification system may meet Power Class 3 requirement, for example as specified by the 3GPP communication standard, when the load control switch is off.

Optionally, an output power of the power amplification system may meet Power Class 2 requirement, for example as specified by the 3GPP communication standard, when the load control switch is on.

Optionally, at least one of the load control capacitors may be a silicon-on-insulator capacitor.

Optionally, the output power control circuit may comprise a plurality of load control switches and a plurality of load control capacitors, each of the load control switches being coupled to one or more of the load control capacitors.

Optionally, the output power control circuit may be configured to provide a plurality of capacitor values alongside the low capacitance having a value close to zero by controlling one or more of the load control switches.

Optionally, the load control switch may be a FET switch.

Optionally, the power amplification system may comprise and/or be connected to one or more power amplifier components configured to provide at least one of advanced power tracking and envelope tracking.

Optionally, one or more parts of the output power control circuit may be controlled by a CMOS control, the CMOS control being configured to receive band and/or power mode controls over a MIPI digital interface.

Optionally, at least one of the transistors may be a heterojunction bipolar transistor.

Optionally, the power amplification system may comprise a frequency response compensation circuit for providing a plurality of values of capacitance. The frequency response compensation circuit comprises at least one tuning capacitor. Each of the at least one tuning capacitor is coupled to a switch for regulating the current path to and/or from the corresponding capacitor to control the value of the capacitance provided by the frequency response compensation circuit. The frequency response compensation circuit is coupled to at least two of the transistors of the power amplifier circuit. The frequency response compensation circuit is configured to reduce variation over frequency of a load impedance of the power amplification system.

According to a number of embodiments of the first aspect, a wireless device comprising: a memory; a user interface; a baseband sub-system; a transceiver; a power management component; and a power amplification system is also provided. The power amplification system comprises: a power amplifier circuit; an output power control circuit for providing a plurality of values of capacitance, and a balun coupled to the power amplifier circuit and to the output power control circuit. The output power control circuit comprises at least one load control capacitor. Each of the at least one load control capacitor is coupled to a load control switch for regulating the current path to and/or from the corresponding capacitor to control the value of the capacitance provided by the output power control circuit.

According to a number of embodiments of the first aspect, a wireless module comprising: a packaging substrate; one or more surface-mount devices; a duplexer assembly; a front-end power management integrated circuit; a match component; an antenna switch module; and a power amplifier assembly comprising a power amplification system is also provided. The power amplification system comprises: a power amplifier circuit; an output power control circuit for providing a plurality of values of capacitance, and a balun coupled to the power amplifier circuit and to the output power control circuit. The output power control circuit comprises at least one load control capacitor. Each of the at least one load control capacitor is coupled to a load control switch for regulating the current path to and/or from the corresponding capacitor to control the value of the capacitance provided by the output power control circuit.

According to a number of embodiments of a second aspect, a power amplification system comprising: a power amplifier circuit, the power amplifier circuit comprising a plurality of transistors; and a frequency response compensation circuit for providing a plurality of values of capacitance is provided. The frequency response compensation circuit comprises at least one tuning capacitor. Each of the at least one tuning capacitors is coupled to a tuning switch for regulating the current path to and/or from the corresponding capacitor to control the value of the capacitance provided by the frequency response compensation circuit. The frequency response compensation circuit is coupled to at least two of the transistors of the power amplifier circuit. The frequency response compensation circuit is configured to reduce variation over frequency of a load impedance of the power amplification system.

Optionally, at least two of the transistors of the power amplifier circuit may be differential transistors.

Optionally, the power amplifier circuit may comprise a push-pull amplifier.

Optionally, the power amplifier circuit may comprise at least one capacitor connected to at least two of the differential transistors.

Optionally, the capacitor connected to the differential transistors may be connected to the drains or collectors of two of the differential transistors.

Optionally, the frequency response compensation circuit may be coupled with at least one of the capacitors connected to at least two of the differential transistors.

Optionally, at least one of the tuning capacitors and at least one of the capacitors connected to at least two of the differential transistors are connected in parallel.

Optionally, a capacitance of the power amplifier circuit may be dependent on one or more of: the value of the capacitor connecting at least two of the differential transistors, the value of the capacitance provided by the frequency response compensation circuit, whether the capacitor connected to at least two of the differential transistors and the frequency response compensation circuit is connected in parallel or in series, and whether the tuning switch is on or off.

Optionally, the frequency response compensation circuit may provide low capacitance having a value close to zero when the tuning switch is off.

Optionally, when the tuning switch is off, the frequency response compensation circuit may not provide additional capacitance to the power amplifier circuit, and the power amplifier circuit may have an impedance value that is suitable for operation at a higher frequency band.

Optionally, when the tuning switch is on, the frequency response compensation circuit may provide additional capacitance to the power amplifier circuit that causes an on-resistance of the amplifier circuit at a lower frequency band to decrease and the PAE of the power amplification system at the lower frequency band to increase.

Optionally, the frequency response compensation circuit may comprise a plurality of tuning switches and a plurality of tuning capacitors, each of the tuning switches being coupled to one or more of the tuning capacitors.

Optionally, the frequency response compensation circuit may be configured to provide a plurality of capacitor values alongside the low capacitance having a value close to zero by controlling one or more of the tuning switches.

Optionally, the tuning switch may be a FET switch.

Optionally, the power amplification system may comprise and/or be connected to one or more power amplifier components configured to provide at least one of advanced power tracking and envelop tracking.

Optionally, at least one of the transistors may be a heterojunction bipolar transistor.

Optionally, one or more part of the frequency response compensation circuit may be controlled by a CMOS control, the CMOS control being configured receive band and/or power mode controls over a MIPI digital interface.

Optionally, the power amplification system may comprise an output power control circuit for providing a plurality of values of capacitance; and a balun coupled to the power amplifier circuit and to the output power control circuit. The output power control circuit comprises at least one load control capacitor. Each of the at least one load control capacitors is coupled to a load control switch for regulating the current path to and/or from the corresponding capacitor to control the value of the capacitance provided by the output power control circuit.

According to a number of embodiments of the second aspect, a wireless device comprising: a memory; a user interface; a baseband sub-system; a transceiver; a power management component; and a power amplification system is also provided. The power amplification system comprises: a power amplifier circuit, the power amplifier circuit comprising a plurality of transistors; and a frequency response compensation circuit for providing a plurality of values of capacitance is provided. The frequency response compensation circuit comprises at least one tuning capacitor. Each of the at least one tuning capacitors is coupled to a tuning switch for regulating the current path to and/or from the corresponding capacitor to control the value of the capacitance provided by the frequency response compensation circuit. The frequency response compensation circuit is coupled to at least two of the transistors of the power amplifier circuit. The frequency response compensation circuit is configured to reduce variation over frequency of a load impedance of the power amplification system.

According to a number of embodiments of the second aspect, a wireless module comprising: A packaging substrate; one or more surface-mount devices; a duplexer assembly; a front-end power management integrated circuit; a match component; an antenna switch module; and a power amplifier assembly comprising a power amplification system is also provided. The power amplification system comprises: a power amplifier circuit, the power amplifier circuit comprising a plurality of transistors; and a frequency response compensation circuit for providing a plurality of values of capacitance. The frequency response compensation circuit comprises at least one tuning capacitor. Each of the at least one tuning capacitors is coupled to a tuning switch for regulating the current path to and/or from the corresponding capacitor to control the value of the capacitance provided by the frequency response compensation circuit. The frequency response compensation circuit is coupled to at least two of the transistors of the power amplifier circuit. The frequency response compensation circuit is configured to reduce variation over frequency of a load impedance of the power amplification system.

The first aspect and second aspect, and any optional features of either, may be combined into a common power amplifier. Such a power amplifier may provide PAE improvement by headroom reduction and PAE bandwidth enhancement across operational frequency.

### BRIEF DESCRIPTION OF THE DRAWINGS

The invention will be described in more detail, by way of example, with reference to the accompanying drawings, in which:

FIG. 1 illustrates an example wireless system or architecture, according to an embodiment;

FIG. 2 illustrates an example amplification system comprising a radio frequency (RF) amplifier assembly having one or more power amplifiers, according to an embodiment;

FIG. 3A to 3E illustrate non-limiting examples of power amplifiers, in accordance with a number of embodiments;

FIG. 4 illustrates an example amplification system implemented as a high-voltage (HV) power amplification system, according to an embodiment;

FIG. 5 illustrates an example power amplification system comprising an amplifier circuit, frequency response compensation circuit, transformer balun, and an output power control circuit, according to an embodiment;

FIG. 6 illustrates a circuit diagram of an example power amplification system comprising an amplifier circuit, frequency response compensation circuit, transformer balun, and an output power control circuit, according to an embodiment;

FIG. 7A is an exemplary graph illustrating how power-added efficiency (PAE) variation over frequency changes depending on the value of a termination capacitor of a balun when a load control switch is off, according to an embodiment;

FIG. 7B is an exemplary graph illustrating how PAE variation over frequency changes depending on the value of a termination capacitor of a balun 519 when a load control switch is on, according to an embodiment;

FIG. 8A is an exemplary Smith Chart according to an embodiment;

FIG. 8B is an exemplary Smith Chart according to an embodiment;

FIG. 9A is an exemplary graph illustrating how a power amplifier load impedance changes over frequency in an exemplary power amplifier system without an output power control circuit, according to an embodiment;

FIG. 9B is an exemplary graph illustrating how a power amplifier load impedance changes over frequency in an exemplary power amplifier system with an output power control circuit, according to an embodiment;

FIG. 10 is an exemplary graph illustrating PAE variation over frequency according to an embodiment;

FIG. 11 illustrates an example wireless module according to an embodiment;

FIG. 12 illustrates an example wireless device according to an embodiment; and

FIG. 14 is an exemplary graph illustrating PAE variation over output power of an exemplary power amplifier configured to support frequency bands that need to operate at different power levels.

### DETAILED DESCRIPTION OF EMBODIMENTS

The embodiments disclosed herein generally relate to power amplifiers for RF communication applications. In accordance with some implementations, the present disclosure relates to a power amplification system. The power amplification system comprises a power amplifier circuit comprising a balun. Although the power amplification system illustrated in the examples of FIG. 5 and FIG. 6 comprises a push-pull amplifier comprising a transformer balun, the amplification system may comprise any other suitable type of power amplifier comprising any other suitable type of transformer balun. The power amplification system may also comprise an output power control circuit coupled to the balun, the output power control circuit being configured to provide a plurality of values of capacitance to control the output power of power amplifier. The power amplification system may also comprise a frequency response compensation circuit coupled to at least two of the transistors of the power amplifier circuit to reduce variation over frequency of a load impedance of the power amplification system. The power amplification system illustrated in the examples of FIG. 5 and FIG. 6 comprises both the output power control circuit and the frequency response compensation circuit. However, in other embodiments, the power amplification system may comprise only one of the output power control circuit and the frequency response compensation circuit.

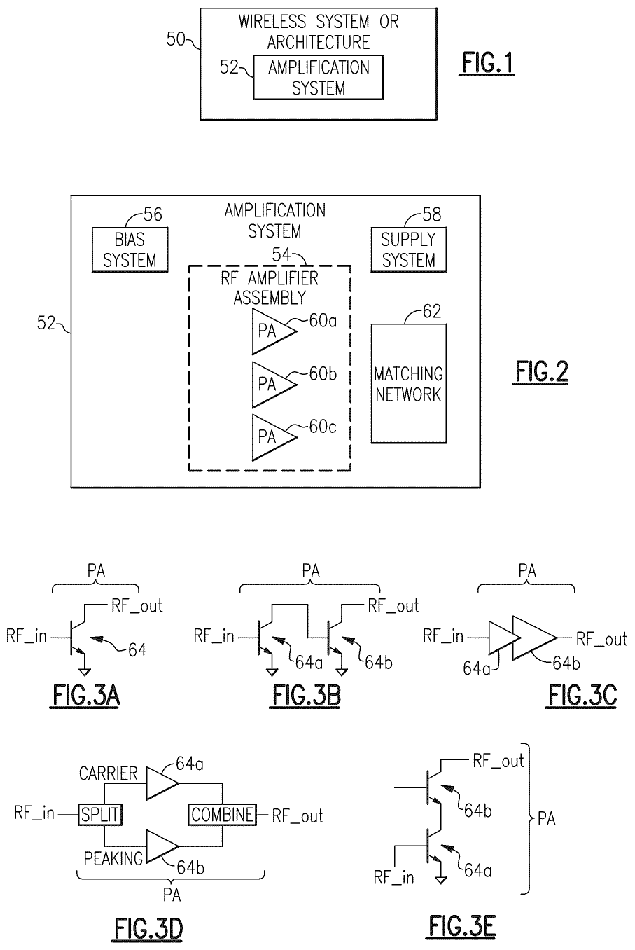

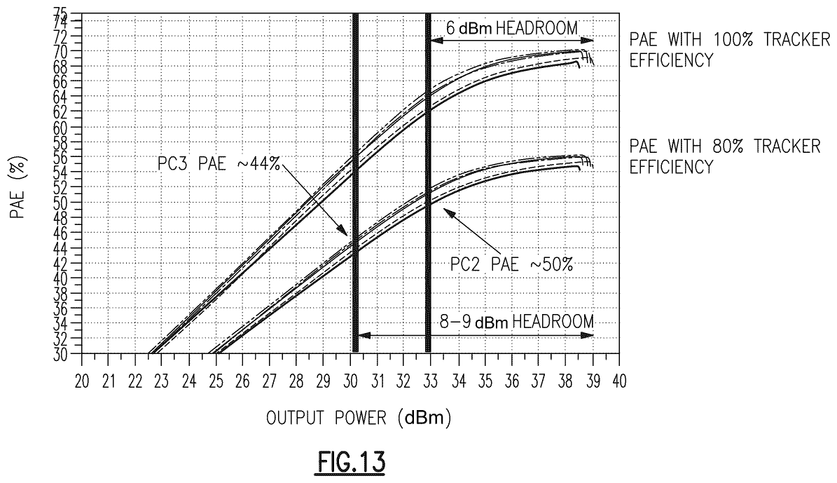

Referring to FIG. 1, embodiments of the present invention may generally be implemented in a wireless system or architecture 50 having an amplification system 52. The amplification system 52 may be implemented as one or more devices, and such device(s) can be utilized in the wireless system/architecture 50. The wireless system/architecture 50 may be implemented in, for example, a portable wireless device. Examples of such a wireless device are described herein with respect to FIG. 12.

FIG. 2 shows that the amplification system 52 of FIG. 1 typically comprises a radio-frequency (RF) amplifier assembly 54 having one or more power amplifiers (PAS). In the example of FIG. 2, three PAs 60a-60c are depicted as forming the RF amplifier assembly 54. It will be understood that other numbers of PA(s) can also be implemented. It will also be understood that one or more features of the present disclosure can also be implemented in RF amplifier assemblies having other types of RF amplifiers.

The RF amplifier assembly 54 may be implemented on one or more semiconductor die, and such die can be included in a packaged module such as a power amplifier module (PAM) or a front-end module (FEM). Such a packaged module is typically mounted on a circuit board associated with, for example, a portable wireless device.

The PAs, e.g., 60a-60c, in the amplification system 52 may be biased by a bias system 56. Further, supply voltages for the PAs may be provided by a supply system 58. Either or both of the bias system 56 and the supply system 58 may be included in the foregoing packaged module having the RF amplifier assembly 54.

The amplification system 52 may include a matching network 62. Such a matching network may be configured to provide input matching and/or output matching functionalities for the RF amplifier assembly 54.

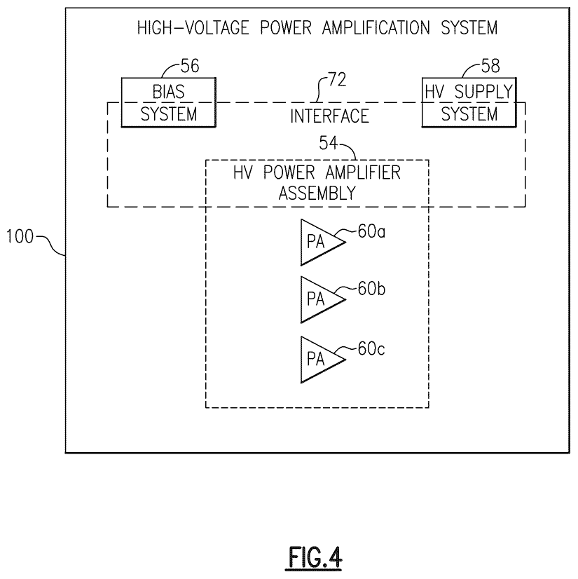

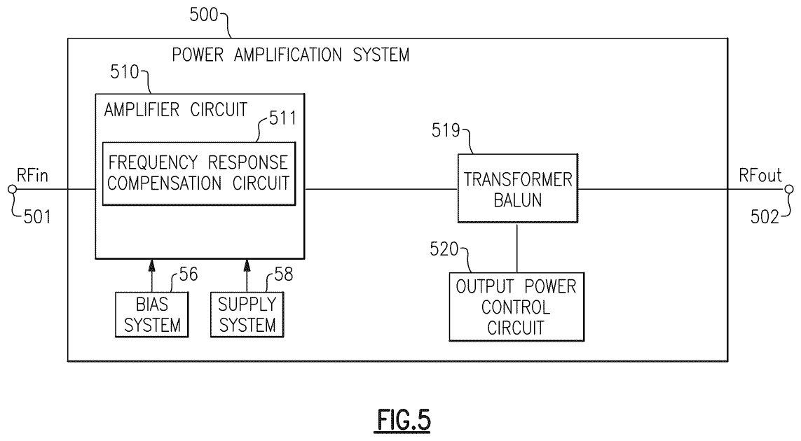

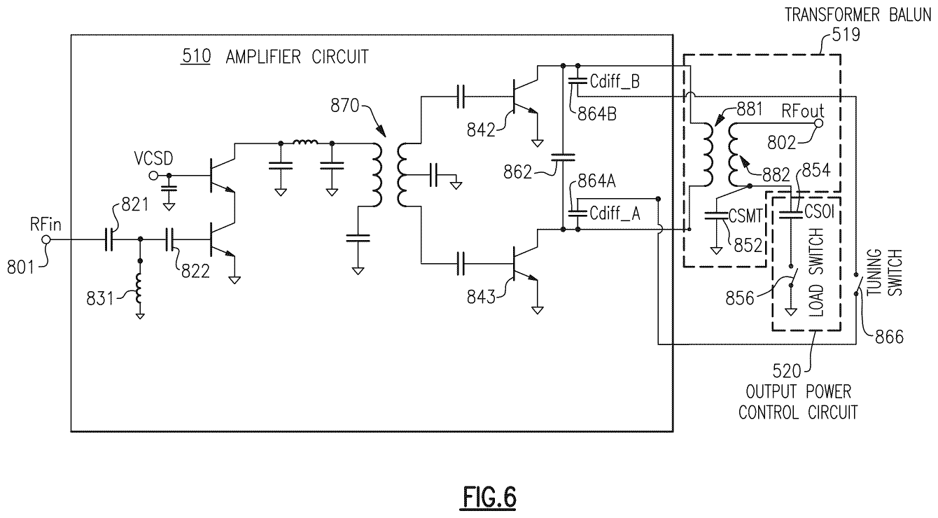

For the purpose of description, it will be understood that each PA 60 of FIG. 2 may be implemented in a number of ways. FIG. 3A-FIG. 3E show non-limiting examples of how such a PA may be configured. FIG. 3A shows an example amplifying transistor 64 that can form a part of the PA, where an input RF signal (RF_in) is provided to a base of the transistor 64, and an amplified RF signal (RF_out) is output through a collector of the transistor 64. A plurality of such amplifying transistors may be included in a PA.

FIG. 3B shows an example PA having a plurality of amplifying transistors, e.g., 64a, 64b, arranged in stages. An input RF signal (RF_in) is provided to a base of the first transistor 64a, and an amplified RF signal from the first transistor 64a is output through its collector. The amplified RF signal from the first transistor 64a is provided to a base of the second transistor 64b, and an amplified RF signal from the second transistor 64b is output through its collector to thereby yield an output RF signal (RF_out) of the PA.

The foregoing example PA configuration of FIG. 3B can be depicted as two or more stages as shown in FIG. 3C. The first stage 64a may be configured as, for example, a driver stage; and the second stage 64b may be configured as, for example, an output stage.

FIG. 3D shows that in some embodiments, a PA may be configured as a Doherty PA. Such a Doherty PA may include amplifying transistors 64a, 64b configured to provide carrier amplification and peaking amplification of an input RF signal (RF_in) to yield an amplified output RF signal (RF_out). The input RF signal may be split into the carrier portion and the peaking portion by a splitter. The amplified carrier and peaking signals may be combined to yield the output RF signal by a combiner.

FIG. 3E shows that in some embodiments, a PA may be implemented in a cascode configuration. An input RF signal (RF_in) may be provided to a base of the first amplifying transistor 64 a operated as a common emitter device. The output of the first amplifying transistor 64a may be provided through its collector and be provided to an emitter of the second amplifying transistor 64b operated as a common base device. The output of the second amplifying transistor 64b may be provided through its collector so as to yield an amplified output RF signal (RF_out) of the PA.

In the various examples of FIG. 3A-FIG. 3E, the amplifying transistors are described as bipolar junction transistors (BJTs) such as heterojunction bipolar transistors (HBTs). It will be understood that one or more features of the present disclosure may also be implemented in or with other types of transistors such as field-effect transistors (FETs). For simplicity, throughout the disclosure, a “gate” or a “base” of a transistor will be referred to as a “base”, a “drain” or a “collector” of a transistor will be referred to as a “collector”, and a “source” or an “emitter” will be referred to as a “emitter”.

FIG. 4 shows that in some embodiments, the amplification system 52 of FIG. 2 may be implemented as a high-voltage (HV) power amplification system 100. Such a system may include an HV power amplifier assembly 54 configured to include HV amplification operation of some or all of the PAs e.g., 60a-60c. As described herein, such PAs may be biased by a bias system 56. The foregoing HV amplification operation may be facilitated by an HV supply system 58. An interface system 72 may be implemented to provide interface functionalities between the HV power amplifier assembly 54 and either or both of the bias system 56 and the HV supply system 58.

For the purpose of description, it will be understood that high-voltage (HV) can include voltage values that are higher than a battery voltage utilized in portable wireless devices. For example, an HV can be greater than 3.7V or 4.2V. In some situations, an HV can include voltage values that are greater than a battery voltage and at which portable wireless devices can operate more efficiently. In some situations, an HV can include voltage values that are greater than a battery voltage and less than a breakdown voltage associated with a given type of PA. In the example context of GaAs heterojunction bipolar transistor (HBT), such a breakdown voltage can be in a range of 15V to 25V. Accordingly, an HV for GaAs HBT PA can be in a range of, for example, 3.7V to 25V, 4.2V to 20V, 5V to 15V, 6V to 14V, 7V to 13V, or 8V to 12V.

Disclosed are examples related to use of a push-pull amplifier including a transformer balun. It will be understood that, although the power amplification system 500 illustrated in the examples of FIG. 5 comprises a push-pull amplifier circuit 510 and a transformer balun 519, in other embodiments, the amplification system 500 may comprise any other suitable type of power amplifier 510 comprising any other suitable type of transformer balun 519.

FIG. 5 illustrates an exemplary power amplification system 500 comprising a push-pull amplifier circuit 510, a frequency response compensation circuit 511, a balun 519 (e.g., transformer balun), and an output power control circuit 520. The frequency response compensation circuit 511, in the example shown in FIG. 5, is included in the amplifier circuit 510. However, in other embodiments, the frequency response compensation circuit 511 may form a part of another part of the power amplification system 500 that is not the amplifier circuit 510, or the frequency response compensation circuit 511 may be a separate part within the power amplification system 500. Similarly, the balun 519, in the example shown in FIG. 5, is not included in the amplifier circuit 510. However, in other embodiments, the balun 519 may form a part of the amplifier circuit 510 or another part of the power amplification system 500.

The power amplification system 500 of FIG. 5 is configured to amplify an input radio-frequency (RF) signal (RFin) received at an input node 501 to generate an output RF signal (RFout) at an output node 502. The output power control circuit 520 is configured to provide two or more values of capacitance. One of the capacitance values that the output power control circuit 520 can provide may be a low value close to zero (in the case of open circuit). As the output power control circuit 520 is coupled to the balun 519, changing the capacitance value provided by the output power control circuit 520 leads to a change of a capacitance value of the balun 519. The balun 519 may comprise a termination capacitor 852. In such cases, the output power control circuit 520 may be coupled to the termination capacitor 852 of the balun 519. In such cases, the total termination capacitance of the balun 519 is determined by: the value of the termination capacitor 852 of the balun 519, the capacitance value provided by the power control circuit 520, and the manner in which the termination capacitor 852 of the balun 519 and the power control circuit 520 are connected (e.g. in parallel or in series). Consequently, switching the capacitance value of the power control circuit 520 enables control of the total termination capacitance of the balun 519, which in turn enables load line control. The switching of the capacitance value of the power control circuit 520 will be discussed further with respect to FIG. 6.

FIG. 13 illustrates power-added efficiency (PAE) variation over output power of an exemplary power amplifier configured to support frequency bands that need to operate at different power levels. In particular, FIG. 13 shows variation over output power for a power amplifier that needs to operate at both Power Class 2 (PC2) and Power Class 3 (PC3) power levels specified by the 3GPP communication standard. In such a case, PC2 requirement sets the maximum power of the power needs because PC2 requires higher output power than PC3. However, this decreases the PAE of the amplifier during PC3 band operation because the power amplifier would still be operating with the maximum output power set by the PC2 requirement. For example, as shown in FIG. 13, the power amplifier may have a suitable level of headroom of ~6 dB during PC2 operation, leading to PAE of ~50% with 80% tracker efficiency, and ~62% with 100% tracker efficiency. However, the power amplifier may have an excessive level of headroom of 8-9 dB during PC3 operation, leading to significantly decreased PAE of ~44% with 80% tracker efficiency, and ~54% with 100% tracker efficiency.

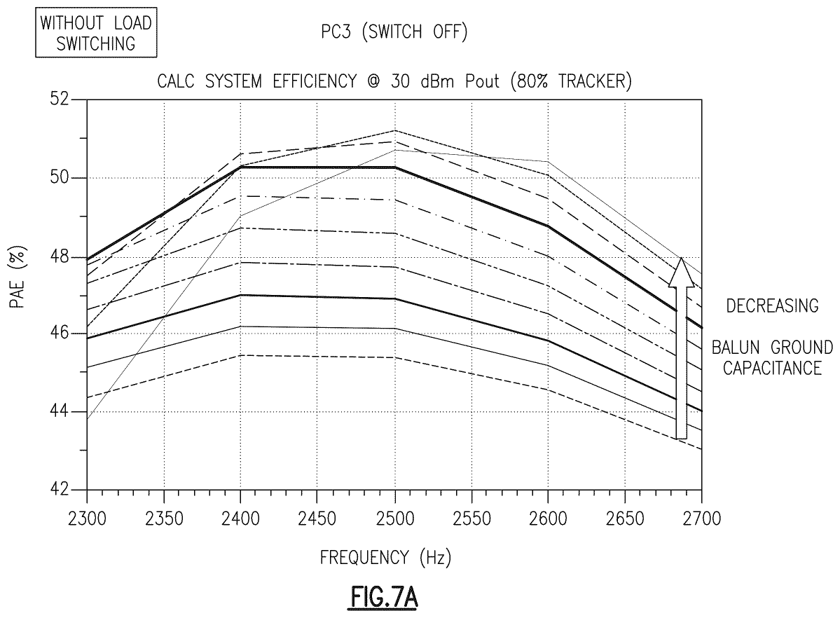

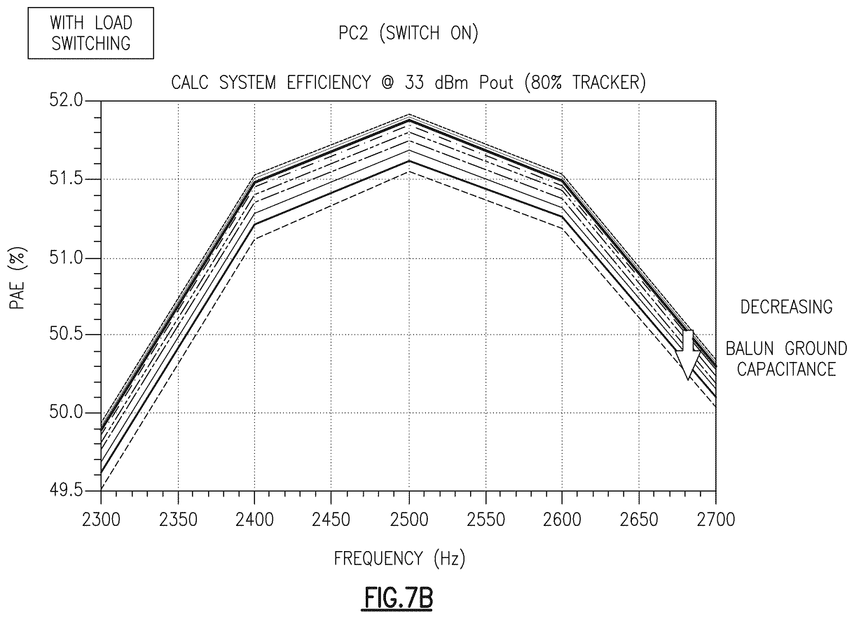

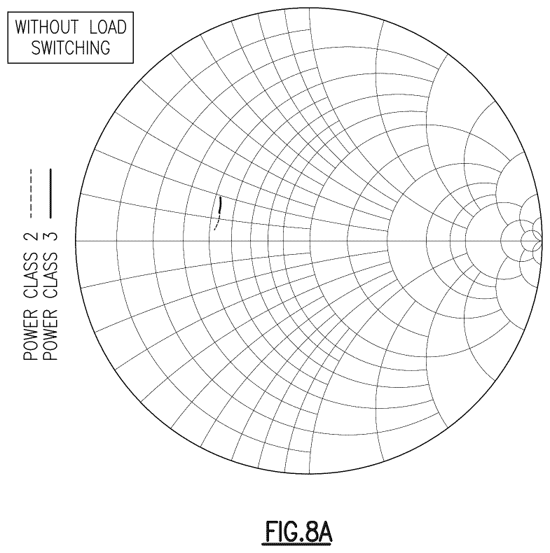

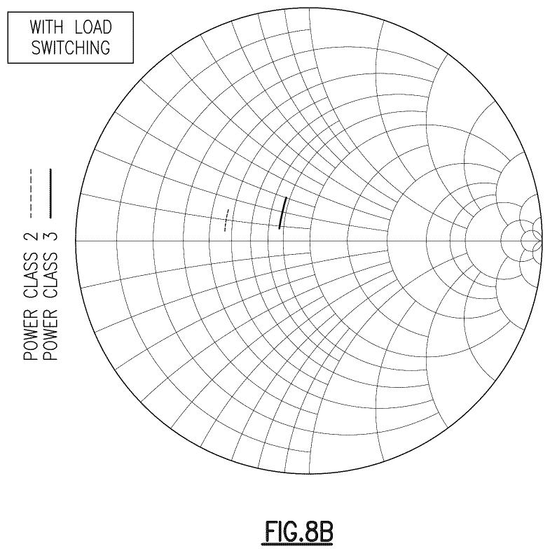

The output power control circuit 520 of FIG. 5 can be particularly useful for improving the power-added efficiency (PAE) of the power amplification system 500 when the power amplification system 500 is configured to accommodate two or more bands of frequencies and/or power modes as shown in the example of FIG. 13. The improvement of the PAE is achieved by adjusting the output power, by controlling the capacitance provided by the output power control circuit 520, according to the output power requirements set by the frequency band of operation. This can minimize unnecessary output power headroom, particularly when the frequency band of operation requires lower output power from the power amplification system 500. The PAE improvement achieved by output power control circuit 520 will be discussed further with respect to FIG. 7-FIG. 9B.

The frequency response compensation circuit 511 is configured to reduce variation over frequency of a number of metrics of the power amplification system 500. For example, the frequency response compensation circuit 511 reduces variation over frequency of a load impedance of the power amplification system 500. The frequency response compensation circuit 511 is configured to provide two or more values of capacitance. One of the capacitance values that the frequency response compensation circuit 511 can provide may be a low value close to zero. The low value that the frequency response compensation circuit 511 can provide may be determined and/or optimized based on a tradeoff between the on-resistance and off-capacitance of the tuning switch 866. Generally, lower off-capacitance of the tuning switch 866 leads to higher on-resistance of the tuning switch 866, and higher on-resistance of the tuning switch 866 may lead to degradation of the PAE of the power amplification system 500 when the tuning switch 866 is on. The frequency response compensation circuit 511 is coupled to at least two of the transistors of the amplifier circuit 510. As a result, changing the capacitance value provided by the frequency response compensation circuit 511 leads to a change of a capacitance value of the amplifier circuit 510. For example, the frequency response compensation circuit 511 may be connected to a collector or an emitter of a first transistor 843 of the amplifier circuit 510 and a collector or an emitter a second transistor 842 of the amplifier circuit 510. The amplifier circuit 510 may optionally comprise a capacitor 862 connecting two of the transistors 842, 843 of the amplifier circuit 510. In such cases, the frequency response compensation circuit 511 may be coupled to the capacitor 862 connecting the two of the transistors 842, 843. In such cases, the total capacitance of the amplifier circuit 510 is dependent on: the value of the capacitor 862 connecting the two of the transistors 842, 843 of the amplifier circuit 510, the capacitance value provided by the frequency response compensation circuit 511, and the manner in which the capacitor 862 connecting the two of the transistors 842, 843 and the frequency response compensation circuit 511 are connected (e.g. in parallel or in series). Consequently, switching the capacitance value of the frequency response compensation circuit 511 enables control of the total capacitance of the amplifier circuit 510, which in turn enables adjustment of reactance of the amplifier circuit 510. The switching of the capacitance value of the frequency response compensation circuit 511 will be discussed further with respect to FIG. 6.

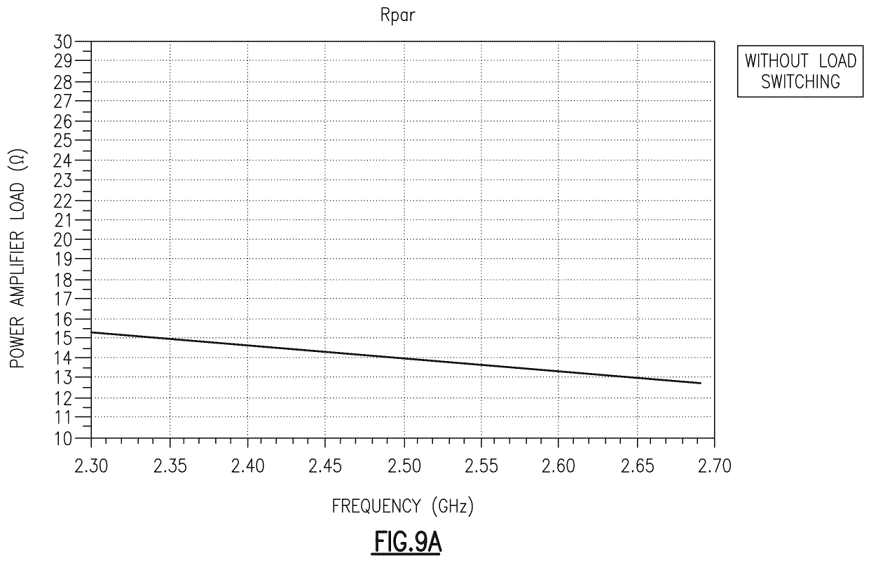

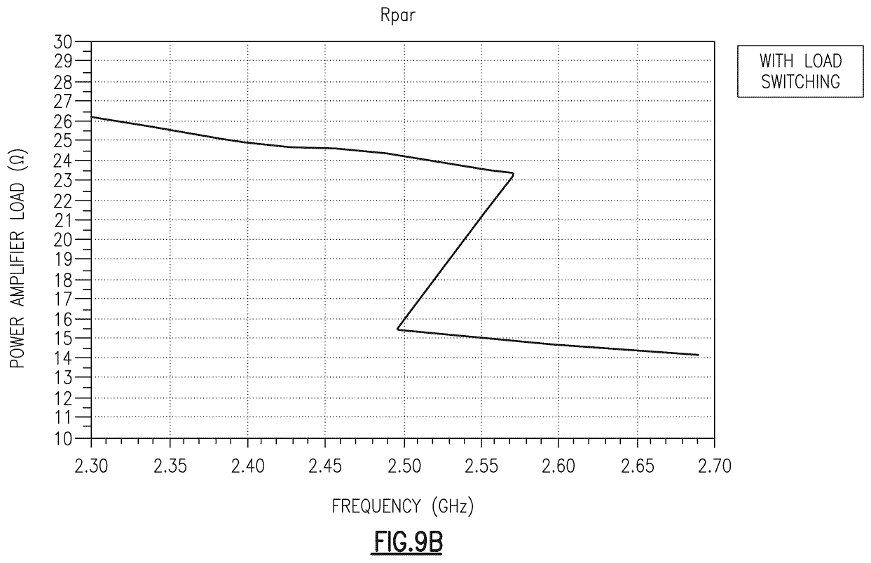

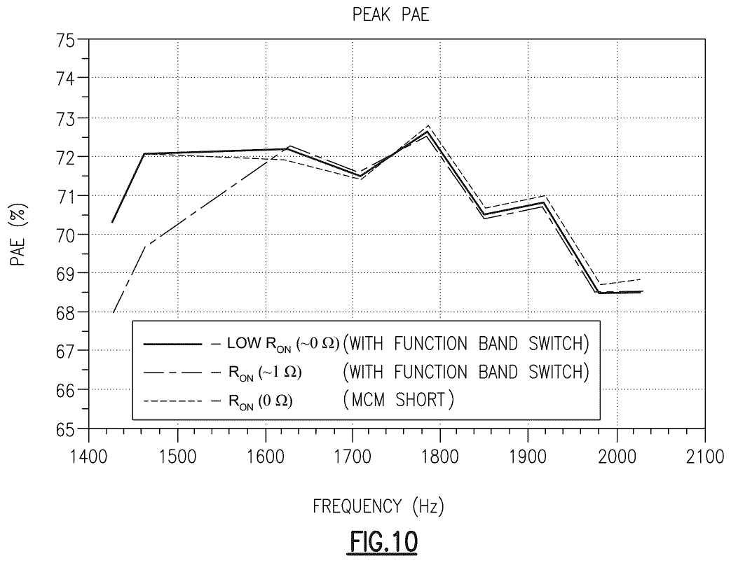

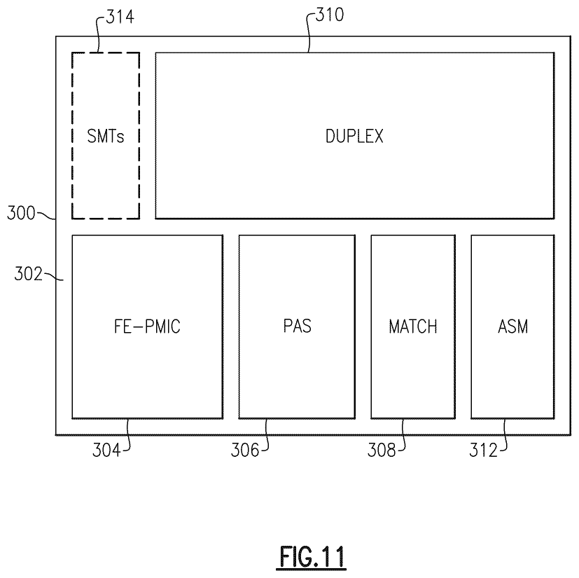

The frequency response compensation circuit 511 can be particularly useful for improving the PAE of the power amplification system 500 when the power amplification system 500 is configured to accommodate a wide bandwidth of frequencies. The improvement of the PAE is achieved by adjusting the reactance of the amplifier circuit 510, by controlling the capacitance provided by the frequency response compensation circuit 511, according to the frequency band of operation. This can reduce variation over frequency of the PAE and/or the saturated output power (Psat) of the power amplification system 500, particularly at lower frequencies. The PAE improvement achieved by the output power control circuit 520 will be discussed further with respect to FIG. 9B, which is an exemplary graph illustrating how a power amplifier load impedance changes over frequency in an exemplary power amplifier system with an output power control circuit, according to an embodiment in FIG. 10.

The power amplification system 500 of FIG. 5 optionally comprises a bias system 56 configured to provide a bias voltage to one or more transistors of the power amplification system 500, and a supply system 58 configured to provide a supply voltage to the amplifier circuit 510. In the example shown in FIG. 5, the bias system 56 and the supply system 58 are not included in the amplifier circuit 510. However, in other embodiments, at least one of the bias system 56 and the supply system 58 may form a part of the amplifier circuit 510 or other part of the power amplification system 500. Alternatively, the bias system 56 and the supply system 58 may be located outside the power amplification system 500. The amplifier circuit 510 may be or may comprise a push-pull amplifier 510.

The power amplifier circuit 510 can be or comprise any of the power amplifiers described above with respect to FIG. 3A-FIG. 3E, a push-pull amplifier, or any other type of power amplifier. The power amplifier circuit 510 comprises an amplifier element configured to amplify the RF signal. The amplifier element may include, for example, one or more transistors. The amplifier element may be powered by a supply voltage (Vcc) and include a connection to a ground voltage. The supply voltage (Vcc) may be provided by the supply system 58.

FIG. 6 illustrates a circuit diagram of an exemplary power amplification system 500 comprising a push-pull amplifier circuit 510, a frequency response compensation circuit 511, a balun 519 (e.g. transformer balun), and an output power control circuit 520. The power amplification system 500 is configured to amplify an input radio-frequency (RF) signal (RFin) received at an input node 801 to generate an output RF signal (RFout) at an output node 802.

The power amplification system 500 may comprise one or more drive transistors. The power amplification system 500 may comprise a first capacitor 821, a second capacitor 822 coupled in series between the input node 801 and the base of at least one of the drive transistor. The power amplification system 500 may comprise a first inductor 831 having a first end coupled to a node between the first capacitor 821 and the second capacitor 822 and having a second end coupled to a ground voltage. The power amplification system 500 may comprise or be connected to a drive bias circuit powered by a supply voltage (Vcc). The drive bias circuit may be coupled to the base of the one or more drive transistors and configured to bias the drive transistor.

The power amplification system 500 may comprise a transformer divider 870. The transformer divider 870 may comprise a first coil and a second coil. A first end of the first coil may be coupled to the collector of the one or more drive transistors and a second end of the first coil may be coupled to the ground voltage via a capacitor. The first end and second end of the second coil may be coupled, via respective capacitors, to respective bases of respective differential transistors 842, 843. Although each of the first end and second end of the second coil in the example of FIG. 6 is coupled to one differential transistor 842, 843, in other embodiments, at least one of the first end and second end of the second coil may be coupled to two or more differential transistors 842, 843.

The power amplification system 500 comprises a balun 519. Although the balun 519 in the example of FIG. 6 is a transformer balun 519, in other embodiments the balun 519 may be any suitable type of balun 519. The balun 519 may comprise a first coil 881 (e.g. a primary coil) and a second coil 882 (e.g. a secondary coil). In such cases, each of the first and second coils 881, 882 comprises a first end and a second end. The first and second ends of the first coil 881 are respectively coupled to the collectors of the differential transistors 842, 843. The second end of the second coil 882 is coupled to the ground voltage via a termination capacitor 852. The termination capacitor 852 in the example of FIG. 6 is optionally a surface-mount capacitor (CSMT). However, in other embodiments the termination capacitor 852 may be any other type of capacitor, such as a silicon-on-insulator (SOI) capacitor or a metal-oxide-semiconductor (MOS) capacitor. The first end of the second coil 882 is coupled to an RF output node 802. Optionally, the balun 519 may be an integrated passive device (IPD) balun.

The power amplification system 500 comprises a frequency response compensation circuit 511 coupled to the differential transistors 842, 843. As shown in the example of FIG. 6, the frequency response compensation circuit 511 may comprise a first tuning capacitor 864A, a tuning switch 866, and a second tuning capacitor 864B connected in series. The first tuning capacitor 864A may be coupled to the collector of the first differential transistor 843, the second tuning capacitor 864B may be coupled to the second differential transistor, and the tuning switch 866 may connect the first and second tuning capacitors 864A, 864B. As shown in the example of FIG. 6, the amplifier circuit 510 may optionally also comprise a capacitor 862 connecting the collectors of the differential transistors 842, 843. In such cases, the frequency response compensation circuit 511 may be coupled to the capacitor 862 connecting the two differential transistors 842, 843. The tuning switch 866 may be any suitable types of switch that can provide on and off modes, such as a FET switch.

When the tuning switch 866 is on, the frequency response compensation circuit 511 connects the tuning capacitor(s) 864A, 864B to the amplifier circuit 510 to provide additional capacitance. On the other hand, when the tuning switch 866 is off, the frequency response compensation circuit 511 forms an open circuit, therefore, the frequency response compensation circuit 511 has no influence on the capacitance of the amplifier circuit 510. In the example of FIG. 6, when the tuning switch 866 is off, the capacitance between the collectors of the first and second differential transistors 842, 843 is equal to the value of the capacitor 862 connecting the collectors of the first and second differential transistors 842, 843. On the other hand, when the tuning switch 866 is on, the capacitance between the collectors of the first and second differential transistors 842, 843 is equal to:

$${C}_{1} + \frac{1}{\frac{1}{{C}_{diff\_A}} + \frac{1}{{C}_{diff\_B}}}$$

wherein C is the value of the capacitor 862 connecting the collectors of the first and second differential transistors 842, 843, C_{diff_A} is the value of the first tuning capacitor 864A, and C_{diff_B} is the value of the second tuning capacitor 864B.

Although in the example of FIG. 6, the frequency response compensation circuit 511 comprises two tuning capacitors 864A, 864B and one tuning switch 866, in other embodiments the frequency response compensation circuit 511 may comprise any number of tuning capacitor(s) 864A, 864B and any number of tuning switch(es) 866 connected in series or parallel. For example, the frequency response compensation circuit 511 may only comprise one tuning capacitor and one tuning switch 866. In such a case, the capacitance between the collectors of the first and second differential transistors 842, 843 is equal to:

$${C}_{1} + {C}_{diff}$$

wherein C₁ is the value of the capacitor 862 connecting the collectors of the first and second differential transistors 842, 843 and C_{diff} is the value of the one tuning capacitor 864A.

It will be understood that, in other embodiments, the capacitor 862 connecting the first and second differential transistors 842, 843 and/or the frequency response compensation circuit 511 may be connected to other parts of the first and second differential transistors 842, 843, such as the emitters, instead of the collectors. It will also be understood that, in other embodiments, the power amplification system 500 may not comprise the capacitor 862 connecting the first and second differential transistors 842, 843. In such cases, the capacitance between the collectors of the first and second differential transistors 842, 843 is equal to the capacitance value of the frequency response compensation circuit 511.

The frequency response compensation circuit 511 may optionally comprise a plurality of tuning switches. In such cases, each of the tuning switches may be coupled to one or more tuning capacitors. Such configurations enables the frequency response compensation circuit 511 to provide a plurality of capacitance values alongside the low capacitance having a value close to zero (in the case of open circuit).

Having such a frequency response compensation circuit 511 in the power amplification system 500 can be particularly useful for improving the PAE of the power amplification system 500 when the power amplification system 500 is configured to accommodate a wide bandwidth of frequencies. The improvement of the PAE is achieved by adjusting the reactance of the amplifier circuit 510, by controlling the capacitance provided by the frequency response compensation circuit 511, according to the frequency band of operation. This can reduce variation over frequency of the PAE and/or the saturated output power (Psat) of the power amplification system 500, particularly at lower frequencies.

FIG. 9B is an exemplary graph illustrating how a power amplifier load impedance changes over frequency in an exemplary power amplifier system with an output power control circuit, according to an embodiment. FIG. 10 is a graph showing an exemplary PAE variation over frequency. Reactance is generally inversely proportional to both capacitance and frequency. In the example of FIG. 9B, which is an exemplary graph illustrating how a power amplifier load impedance changes over frequency in an exemplary power amplifier system with an output power control circuit, according to an embodiment; in FIG. 10, the on-resistance (RON) of the tuning switch 866 has a high value of ~1Ω when additional tuning capacitor(s) 864A, 864B are not connected to the amplifier circuit 510 (i.e. the tuning switch 866 is off). On the other hand, the Row of the tuning switch 866 has a low value close to 0Ω when additional tuning capacitor(s) 864A, 864B are connected to the amplifier circuit 510 (i.e. the tuning switch 866 is on). It can be seen from FIG. 9B, which is an exemplary graph illustrating how a power amplifier load impedance changes over frequency in an exemplary power amplifier system with an output power control circuit, according to an embodiment; in FIG. 10 when the tuning switch 866 is off (R_{ON}≈1), the power amplification system 500 suffers from PAE reduction at lower frequencies. This can be attributed to higher reactance at lower frequency. Such losses of PAE can be compensated by connecting the additional tuning capacitor(s) 864A, 864B to the amplifier circuit 510 by turning the tuning switch 866 on. FIG. 9B is an exemplary graph illustrating how a power amplifier load impedance changes over frequency in an exemplary power amplifier system with an output power control circuit, according to an embodiment. FIG. 10 also illustrates an exemplary PAE variation over frequency (MCM SHORT) for a hypothetical scenario wherein the tuning switch 866 is a perfect switch having zero R_{ON}.

The power amplification system 500 comprises an output power control circuit 511 coupled to the balun 519. As shown in the example of FIG. 6, the output power control circuit 511 may comprise a load control capacitor 854, and a load control switch 856 connected in series. The load control capacitor 854 may be coupled to the second end of the second coil 882 of the balun 519, and the load control capacitor 854 may be coupled to the ground voltage via the load control switch 856. Alternatively, in other embodiments, the load control switch 856 may be coupled to the second end of the second coil 882 of the balun 519, and the load control switch 856 may be coupled to the ground voltage via the load control capacitor 854. As shown in the example of FIG. 6, the balun 519 may comprise a termination capacitor 852 connecting the second end of the second coil 882 of the balun 519 to the ground voltage. In such cases, the output power control circuit 511 may be coupled to the termination capacitor 852. The load control capacitor 854 in the example of FIG. 6 is optionally a silicon-on-insulator (SOI) capacitor (CSOI). However, in other embodiments the load control capacitor 854 may be any other type of capacitor, such as a surface-mount capacitor (CSMT) or a metal-oxide-semiconductor (MOS) capacitor. The load control switch 856 may be any suitable types of switch that can provide on and off modes, such as a FET switch.

When the load control switch 856 is on, the output power control circuit 511 connects the load control capacitor 854 to the balun 519 to provide additional capacitance. On the other hand, when the load control switch 856 is off, the output power control circuit 511 forms an open circuit, therefore, the output power control circuit 511 has no influence on the capacitance of the balun 519. In the example of FIG. 6, when the load control switch 856 is off, the capacitance between the second end of the second coil 882 of the balun 519 and the ground is equal to the value of the termination capacitor 852, C_{SMT}. On the other hand, when the load control switch 856 is on, the capacitance between the second end of the second coil 882 of the balun 519 and the ground is equal to:

$${C}_{SMT} + {C}_{SOI}$$

wherein C_{SMT} is the termination capacitor 852 and C_{SOI} is the value of the load control capacitor 854.

Although in the example of FIG. 6, the output power control circuit 511 comprises one load control capacitor 854 and one load control switch 856, in other embodiments the output power control circuit 511 may comprise any number of load control capacitors and load control switch(es).

It will be understood that, in other embodiments, the termination capacitor 852 and/or the output power control circuit 511 may be connected to other parts of the balun 519, such as a node located between the first and second ends of the second coil 882, instead of the second end of the second coil 882. It will also be understood that, in other embodiments, the balun 519 may not comprise the termination capacitor 852. In such cases, the capacitance between the balun 519 and the ground is equal to the capacitance value of the output power control circuit 511.

The output power control circuit 511 may optionally comprise a plurality of load control switches. In such cases, each of the load control switches may be coupled to one or more load control capacitors. Such configurations enable the output power control circuit 511 to provide a plurality of capacitance values alongside the low capacitance having a value close to zero (in the case of open circuit).

The output power control circuit 520 can be particularly useful for improving the PAE of the power amplification system 500 when the power amplification system 500 is configured to accommodate two or more bands of frequencies and/or power modes. The improvement of the PAE is achieved by adjusting the output power, by controlling the capacitance provided by the output power control circuit 520, according to the output power requirements set by the frequency band of operation. This can minimize unnecessary output power headroom, particularly when the frequency band of operation requires lower output power from the power amplification system 500.

FIG. 7A is an exemplary graph illustrating how PAE variation over frequency changes depending on the value of the termination capacitor 852 of the balun 519 when the load control switch 856 is off. As one mode of operation (e.g. PC3 operation) requires lower output power than another mode of operation (e.g. PC2 operation), it may be preferable to decrease the capacitance of the balun 519. The capacitance of the balun 519 may be decreased by turning off the load control switch 856 and optionally replacing the termination capacitor 852 of the balun 519 with a capacitor having a lower value.

However, decreasing the capacitance of the balun can be problematic for higher power operation, such as PC2 operation which requires higher output power than PC3 operation. The output power control circuit 520 can be particularly useful in such cases, as it can provide additional capacitor(s) that can be connected to and disconnected from the balun 519 depending on the required output power. FIG. 7B is an exemplary graph illustrating how PAE variation over frequency changes depending on the value of the termination capacitor 852 of the balun 519 when the load control switch 856 is on. In this case, for PC2 operation, the output power control circuit 520 can provide additional capacitance to the balun 519 in addition to the optimal capacitance value of the balun 519 for PC3 operation.

FIG. 9A illustrates how the power amplifier load impedance changes over frequency in an exemplary power amplifier system without the output power control circuit 520. The graph shows that the load impedance is inversely proportional to the frequency. FIG. 8A illustrates a corresponding Smith Chart, showing that the output power of the amplifier system without the output power control circuit 520 is not adapted depending on the band of frequencies and/or power modes.

On the other hand, FIG. 9B illustrates how the power amplifier load impedance changes over frequency in an exemplary power amplifier system with the output power control circuit 520. Unlike the example of FIG. 9A and FIG. 8A, the output power control circuit 520 enables the load impedance to be increased for PC3 band and decreased for PC2 band. In the example shown in FIG. 9B, the switching of the output power control circuit 520 takes place at ~2570 Hz. FIG. 8B illustrates a corresponding Smith Chart, showing that the output power of the amplifier system with the output power control circuit 520 is adapted depending on the band of frequencies and/or power modes.

Using the output power control circuit 520 in this way can provide an easy way to switch between a plurality of selectable capacitance values of the balun 519 depending on the required output power.

Whilst the output power control circuit 520 has been described, in relation to FIG. 5 and FIG. 6, as being provided in combination with the frequency response compensation circuit 511, this is not required. Either can be implemented alone without the other. That is, embodiments of the power amplification system 500 that are implemented without the frequency response compensation circuit 511 may not comprise the one or more of the parts and/or components shown in FIG. 5 and/or FIG. 6, including: the tuning capacitor(s) 864A, 864B, the tuning switch 866, and the capacitor 862 connecting two of the transistors 842, 843. Similarly, embodiments of the power amplification system 500 that are implemented without the output power control circuit 520 may not comprise the one or more of the parts and/or components shown in FIG. 5 and/or FIG. 6, including: the load control capacitor 854, the load control switch 856, and the balun 519 or one or more parts of the balun 519 such as the termination capacitor 852 connecting the second coil 882 of the balun 519 to the ground.

In embodiments of the power amplification system 500 that are implemented with both the output power control circuit 520 and the frequency response compensation circuit 511, such as the power amplification system 500 according to FIG. 5 and FIG. 6, the features and advantages of the output power control circuit 520 and the frequency response compensation circuit 511 may be cooperated in a synergistic manner to allow effective PAE improvement over an extended bandwidth. As discussed with respect to FIG. 7, FIG. 8A, FIG. 8B, FIG. 9A FIG. 9B and FIG. 13, the output power control circuit 520 improves PAE by minimizing unnecessary power headroom, whereas, as discussed with respect to FIG. 9B, which is an exemplary graph illustrating how a power amplifier load impedance changes over frequency in an exemplary power amplifier system with an output power control circuit, according to an embodiment. In FIG. 10, the frequency response compensation circuit 511 improves PAE across extended bandwidth. In other words, the output power control circuit 520 controls the real part of the load impedance which affects the output power of the power amplification system 500, and the frequency response compensation circuit 511 controls the imaginary part of the load impedance which affects the frequency response of the power amplification system 500. Therefore, the combination of the output power control circuit 520 and the frequency response compensation circuit 511 can synergistically improve the parameters of the power amplification system 500 that are dependent on both the real and imaginary parts of the load impedance, such as PAE. Furthermore, combining the output power control circuit 520 and the frequency response compensation circuit 511 can provide PAE enhancement across extended bandwidth at the same time as meeting various requirements set by size constraints of the power amplification system 500 and/or devices comprising the power amplification system 500.

One or more advantageous features of the power amplification system 500 described herein may be combined with one or more other types of power amplifier architectures. For example, advanced power tracking and/or envelope tracking techniques and/or architectures may be used in conjunction with at least one of the output power control circuit 520 and the frequency response compensation circuit 511.

Optionally, one or more parts of the output power control circuit 520 and/or the frequency response compensation circuit 511 may be controlled by a CMOS control. In such cases, the CMOS control may be configured to receive band and/or power mode controls over a MIPI digital interface.

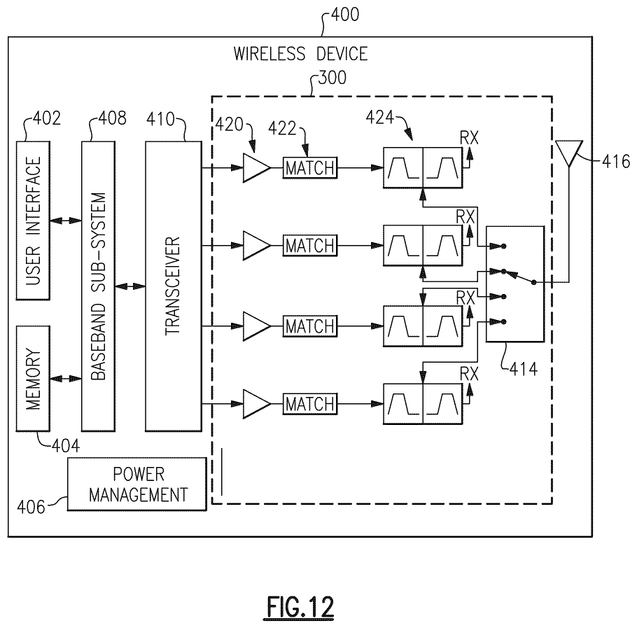

As illustrated in FIG. 11, all or at least a part of the power amplification system 500 may be implemented in a module 300. Such a module 300 may be, for example, a front-end module (FEM). In the example of FIG. 11, a module 300 may comprise a packaging substrate 302, and a number of components may be mounted on such a packaging substrate. For example, a Front-end Power Management Integrated Circuit (FE-PMIC) component 304, a power amplifier assembly 306, a match component 308, and a duplexer assembly 310 may be mounted and/or implemented on and/or within the packaging substrate 302. The power amplifier assembly 306 may comprise at least a part of the frequency response compensation circuit 511 and/or at least a part of the output power control circuit 520, such as those described above with respect to FIG. 5 and FIG. 6. The power amplifier assembly 306 may include a push-pull amplifier and a transformer balun. Other components such as a number of SMT (surface-mount technology) devices 314 and an antenna switch module (ASM) 312 may also be mounted on the packaging substrate 302. Although all of the various components are depicted as being laid out on the packaging substrate 302, it will be understood that some component(s) can be implemented over other component(s).

In some implementations, a device and/or a circuit having one or more features described herein may be included in an RF device such as a wireless device. Such a device and/or a circuit may be implemented directly in the wireless device, in a modular form as described herein, or in some combination thereof. Such a wireless device may include, for example, a cellular phone, a smartphone, a hand-held wireless device with or without phone functionality, a wireless tablet, etc.

FIG. 12 illustrates an example wireless device 400 having one or more advantageous features described herein. In the context of a module having one or more features as described herein, such a module may be generally depicted by a dashed box 300, and can be implemented as, for example, a front-end module (FEM).

Referring to FIG. 12, power amplifiers (PAs) 420 may receive their respective RF signals from a transceiver 410 that can be configured and operated in known manners to generate RF signals to be amplified and transmitted, and to process received signals. The transceiver 410 may interact with a baseband sub-system 408 that is configured to provide conversion between data and/or voice signals suitable for a user and RF signals suitable for the transceiver 410. The transceiver 410 can also be in communication with a power management component 406 that is configured to manage power for the operation of the wireless device 400. Such power management can also control operations of the baseband sub-system 408 and the module 300. The baseband sub-system 408 may be connected to a user interface 402 to facilitate various input and output of voice and/or data provided to and received from the user. The baseband sub-system 408 may also be connected to a memory 404 that is configured to store data and/or instructions to facilitate the operation of the wireless device, and/or to provide storage of information for the user.

In the example shown in FIG. 12, wireless device 400 outputs of the PAs 420 may be matched via respective match circuits 422 and routed to their respective duplexers 424. Such amplified and filtered signals may be routed to an antenna 416 through an antenna switch 414 for transmission. Optionally, the duplexers 424 may allow transmit and receive operations to be performed simultaneously using a common antenna 416. Received signals may be routed to “Rx” paths that may comprise, for example, a low-noise amplifier (LNA).

A number of other wireless device configurations may utilize one or more features described herein. For example, a wireless device does not need to be a multi-band device. In another example, a wireless device may include additional antennas such as a diversity antenna, and additional connectivity features such as Wi-Fi, Bluetooth, and GPS.

As described herein, one or more features of the present disclosure may provide a number of advantages when implemented in systems such as those involving the wireless device of FIG. 12. For example, the disclosed architecture may greatly improve the usable bandwidth of a push-pull amplifier.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplification system comprising:
a power amplifier circuit including at least two differential transistors and at least one capacitor connected to the at least two differential transistors, and at least one tuning capacitor coupled in parallel with the at least one capacitor;
a balun coupled to the power amplifier circuit; and
an output power control circuit coupled to the balun, the output power control circuit including at least one load control capacitor coupled to a load control switch to control a value of capacitance provided by the output power control circuit.

2. The power amplification system of claim 1, wherein the power amplifier circuit comprises a push-pull amplifier.

3. The power amplification system of claim 1, wherein at least one of the at least two differential transistors is a heterojunction bipolar transistor.

4. The power amplification system of claim 1, wherein the balun comprises a first coil having a first end and a second end, the first end of the first coil coupled to a first differential transistor of the at least two differential transistors, and the second end of the first coil being coupled to a second differential transistor of the at least two differential transistors.

5. The power amplification system of claim 4, wherein the first end of the first coil is coupled to a drain or a collector of the first differential transistor and the second end of the first coil is coupled to a drain or a collector of the second differential transistor.

6. The power amplification system of claim 1, wherein the balun comprises a second coil having a first end and a second end, the first end of the second coil being coupled to a radio frequency output node and the second end of the second coil being coupled to a ground.

7. The power amplification system of claim 6, wherein the second end of the second coil is coupled to the output power control circuit.

8. The power amplification system of claim 6, wherein the second end of the second coil is coupled to one or more termination capacitors.

9. The power amplification system of claim 8, wherein at least one of the one or more termination capacitors is a surface-mount capacitor.

10. The power amplification system of claim 1, wherein the balun is further coupled with at least one termination capacitor.

11. A wireless device comprising:
a baseband sub-system;
a transceiver;
a power management component; and
a power amplification system, the power amplification system including a power amplifier having at least two differential transistors and at least one capacitor connected to the at least two differential transistors and at least one tuning capacitor coupled in parallel with the at least one capacitor, a balun coupled to the power amplifier, and an output power control circuit coupled to the balun, the output power control circuit having at least one load control capacitor coupled to a load control switch to control a value of capacitance provided by the output power control circuit.

12. The wireless device of claim 11, wherein the balun comprises a first coil having a first end and a second end, the first end of the first coil coupled to a first differential transistor of the at least two differential transistors, and the second end of the first coil being coupled to a second differential transistor of the at least two differential transistors.

13. The wireless device of claim 12, wherein the balun comprises a second coil that is coupled with at least one termination capacitor.

14. The wireless device of claim 13, wherein at least one load capacitor and at least one termination capacitor are connected in parallel.

15. The wireless device of claim 11, wherein a capacitance of the balun is dependent on one or more of: a value of one or more termination capacitors coupled to the balun, a value of the at least one load control capacitor, whether the one or more termination capacitors and the output power control circuit is connected in parallel or in series, and whether the load control switch is on or off.

16. The wireless device of claim 11, wherein the output power control circuit provides low capacitance having a value close to zero when the load control switch is off.

17. The wireless device of claim 11, wherein when the load control switch is off, the output power control circuit does not provide additional capacitance to the balun, and the power amplification system has a load impedance value that leads to a lower output power.

18. The wireless device of claim 11, wherein when the load control switch is on, the output power control circuit provides additional capacitance to the balun, causing a load impedance value to decrease and output power of the power amplification system to increase to a higher output power.

19. The wireless device of claim 11, wherein the power amplification system comprises and/or is connected to one or more power amplifier components configured to provide at least one of advanced power tracking and envelop tracking.

20. The wireless device of claim 11, wherein one or more parts of the output power control circuit are controlled by a CMOS control, the CMOS control being configured to receive band and/or power mode controls over a MIPI digital interface.
